(19) United States
(12) Patent Application Publication
(10) Pub. No.: US 2026/0305211 A1
(43) Pub. Date: Oct. 1, 2026

(54) PACKAGE STRUCTURE AND METHOD OF MANUFACTURING THE SAME

(71) Applicant: Advanced Semiconductor Engineering, Inc., Kaohsiung (TW)

(72) Inventors: Tsung Chi WU, Kaohsiung (TW); Fu Tang CHU, Kaohsiung (TW); Bo Hua CHEN, Kaohsiung (TW); Wen-Pin HUANG, Kaohsiung (TW)

(73) Assignee: Advanced Semiconductor Engineering, Inc., Kaohsiung (TW)

(21) Appl. No.: 19/097,849

(22) Filed: Apr. 1, 2025

(51) Int. Cl. H01L 21/78; H01L 23/544

(52) U.S. Cl. CPC H10P 54/00; H10W 46/00; H10W 46/201

(57) ABSTRACT

A package structure and a method of manufacturing a package structure are provided. The method includes providing a structure including a substrate and a metal-containing structure over the substrate; applying a first laser beam to a first surface of the structure, the first laser beam having a first beam size and at least a first intensity; applying a second laser beam to the first surface of the structure, wherein the second laser beam has a second beam size less than the first beam size and a second intensity higher than the first intensity; and breaking the structure from a second surface opposite to the first surface of the structure.

### BACKGROUND

### 1. Technical Field

The present disclosure relates generally to a package structure and a method of manufacturing a package structure. Specifically, the present disclosure relates to a package structure and a method of manufacturing a package structure by applying laser beams.

### 2. Description of the Related Art

Power devices may be manufactured by forming circuits and interconnection structures over a silicon carbide (SiC) wafer followed by singulating the SiC wafer to form a plurality of power devices. However, SiC has a relatively high hardness which may result in lower yields of the manufacturing process for forming the power devices.

### SUMMARY

In one or more arrangements, a method of manufacturing a package structure includes providing a structure including a substrate and a metal-containing structure over the substrate; applying a first laser beam to a first surface of the structure, the first laser beam having a first beam size and at least a first intensity; applying a second laser beam to the first surface of the structure, wherein the second laser beam has a second beam size less than the first beam size and a second intensity higher than the first intensity; and breaking the structure from a second surface opposite to the first surface of the structure.

In one or more arrangements, a package structure includes a substrate and a metal-containing structure. The substrate has an upper surface, a lower surface, and a first lateral surface extending between the upper surface and the lower surface. The substrate includes a first stepped structure defined by the upper surface and the first lateral surface and has a non-uniform roughness. The metal-containing structure is over the upper surface.

In one or more arrangements, a package structure includes a substrate, a circuit structure, and a first microstructure layer. The substrate has an upper surface, a lower surface, and a first lateral surface extending between the upper surface and the lower surface. The circuit structure is over a first portion of the upper surface. The first microstructure layer includes a plurality of first particles over a first portion of the first lateral surface and is free from covering a second portion of the first lateral surface.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A, FIG. 1B, FIG. 1C, FIG. 1D, FIG. 1E, FIG. 1F, FIG. 1G, FIG. 1H, FIG. 1I, and FIG. 1J illustrate various stages of an example of a method of manufacturing a package structure in accordance with some arrangements of the present disclosure.

FIG. 2A is a cross-section of a package structure in accordance with some arrangements of the present disclosure.

FIG. 2B is a cross-section of a portion of a package structure in accordance with some arrangements of the present disclosure.

FIG. 2C is a cross-section of a package structure in accordance with some arrangements of the present disclosure.

FIG. 3A, FIG. 3B, FIG. 3C, FIG. 3D, and FIG. 3E illustrate various stages of an example of a method of manufacturing a package structure in accordance with some arrangements of the present disclosure.

FIG. 4A is a cross-section of a package structure in accordance with some arrangements of the present disclosure.

FIG. 4B is a cross-section of a portion of a package structure in accordance with some arrangements of the present disclosure.

FIG. 4C is a cross-section of a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

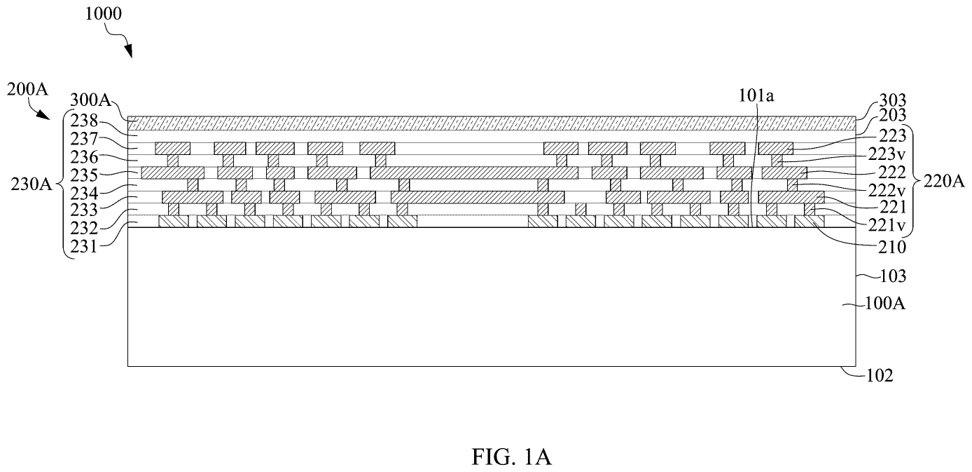

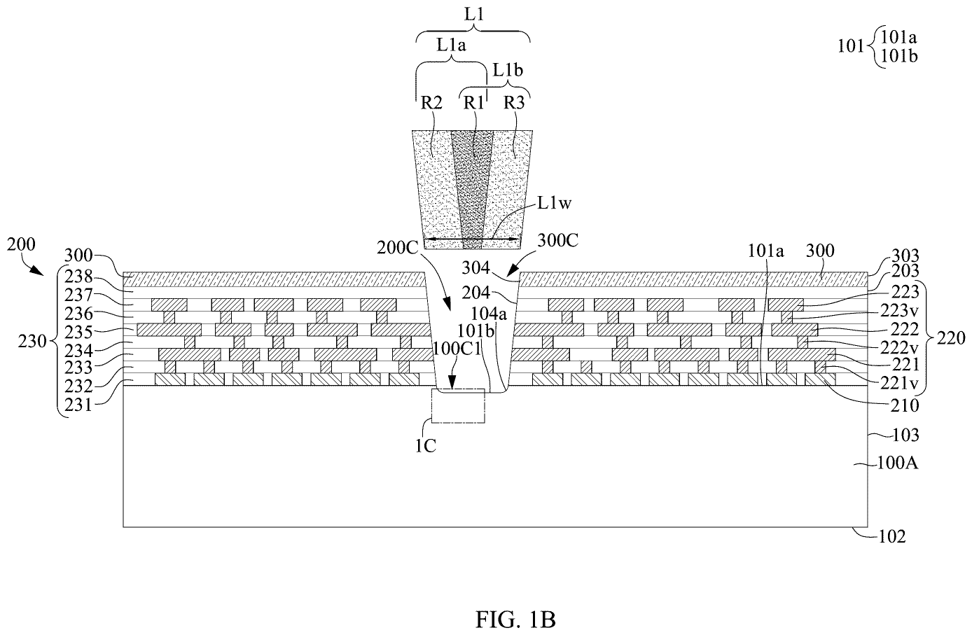

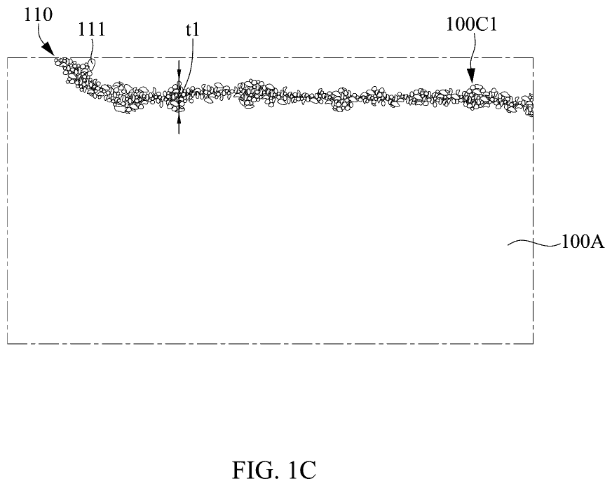

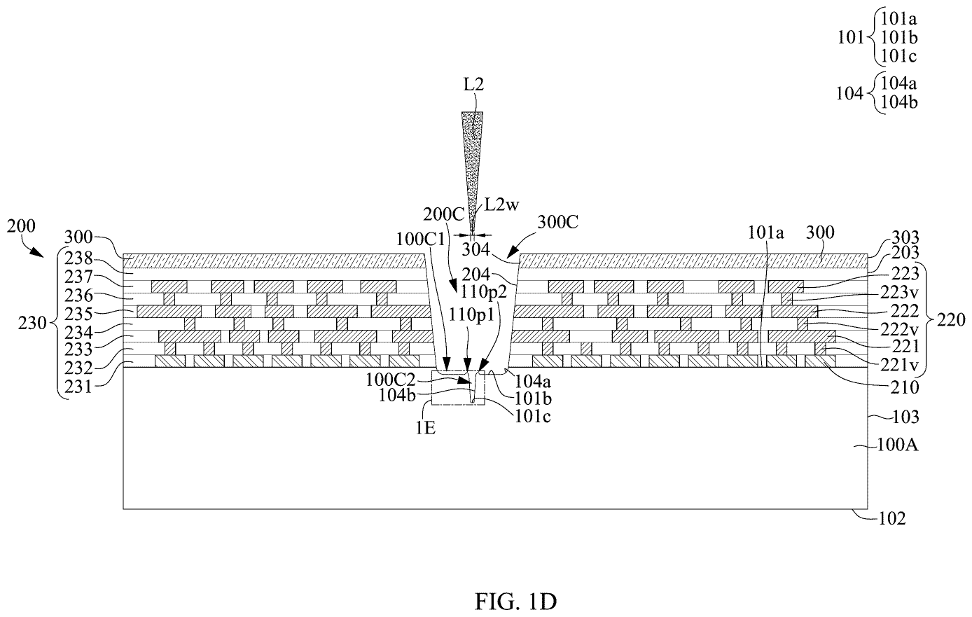

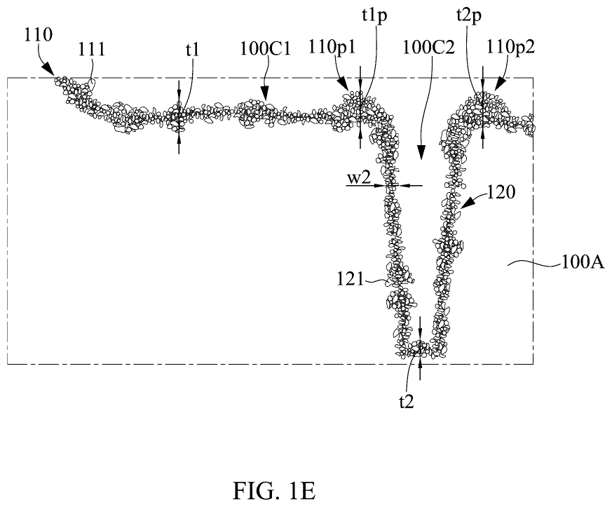

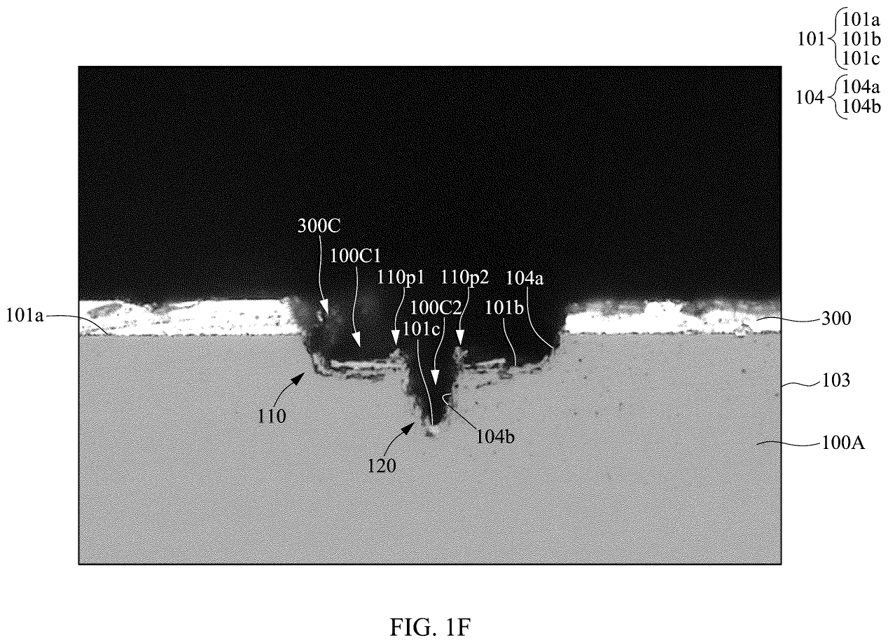

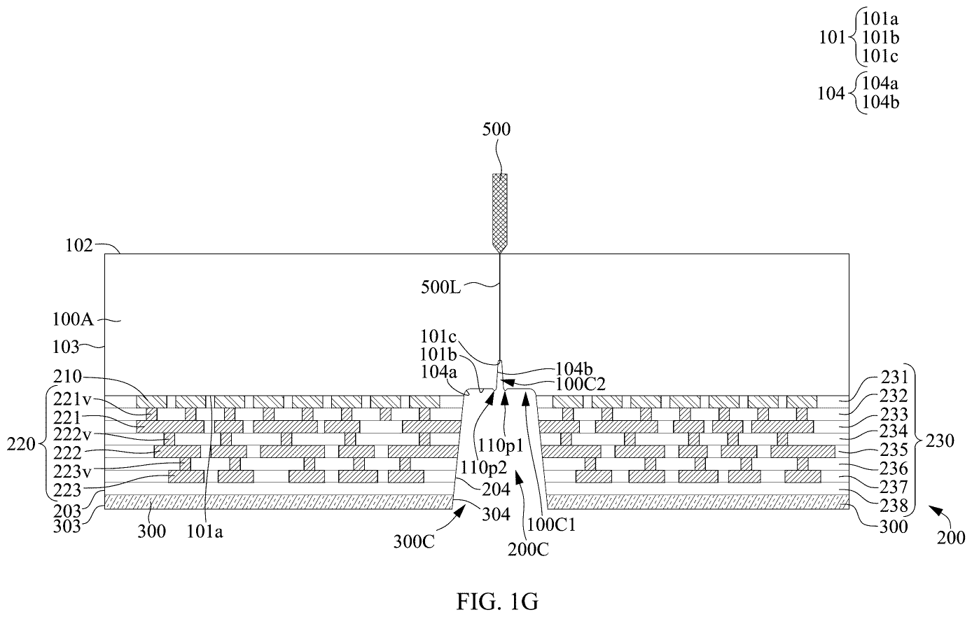

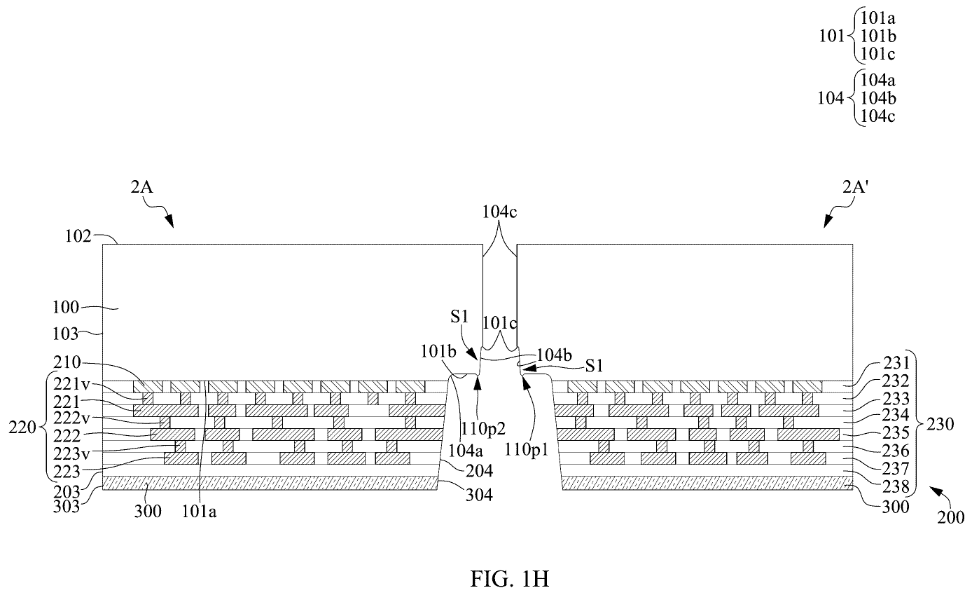

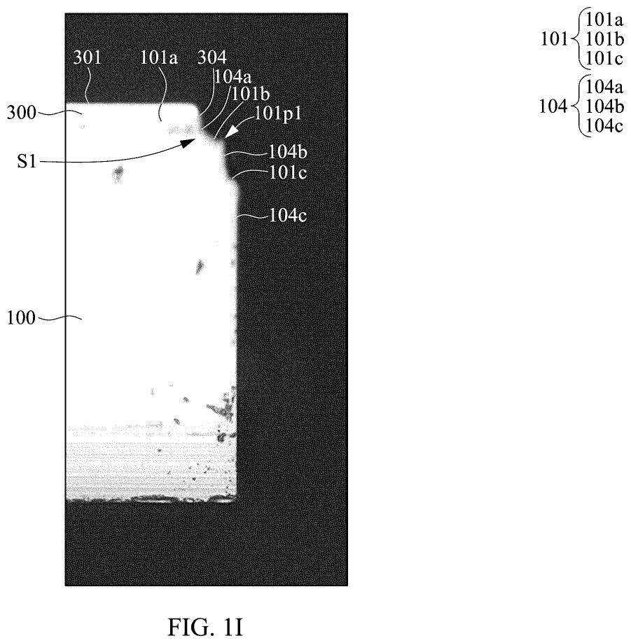

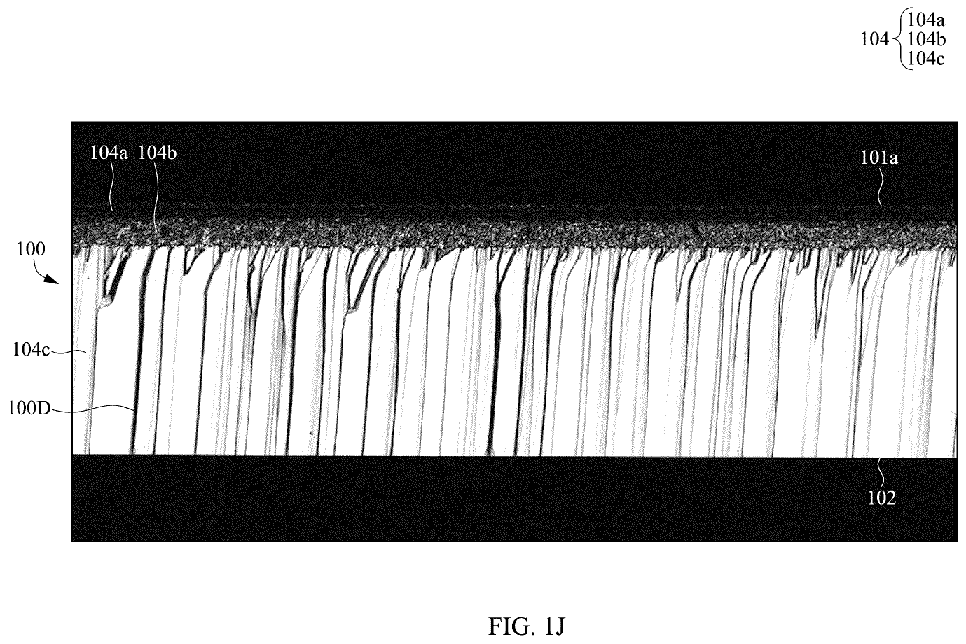

FIG. 1A, FIG. 1B, FIG. 1C, FIG. 1D, FIG. 1E, FIG. 1F, FIG. 1G, FIG. 1H, and FIG. 1I illustrate various stages of an example of a method of manufacturing a package structure in accordance with some arrangements of the present disclosure.

Referring to FIG. 1A, a structure 1000 may be provided. In some arrangements, a metal-containing structure is disposed or formed over a substrate 100A to provide or form the structure 1000. A metal cover 300A may be disposed or formed over a circuit structure 200A to form the metal-containing structure. The structure 1000 may be referred to as a wafer structure or a wafer-level structure.

In some arrangements, the substrate 100A is or includes a wafer or a wafer substrate. The substrate 100A may have a surface 101a (also referred to as “an upper surface” or “a top surface”), a surface 102 (also referred to as “a lower surface” or “a bottom surface”), and lateral surfaces 103 extending between the surface 101a and the surface 102. The surface 101a may be referred to as an active surface. In some arrangements, the substrate 100A has a hardness or a rigidity greater than a hardness or a rigidity of a silicon (Si) substrate. The substrate 100A may include a semiconductor material. In some arrangements, the substrate 100A is or includes a silicon carbide (SiC) substrate.

In some arrangements, the circuit structure 200A is or includes a wafer-level circuit structure. The circuit structure 200A may have lateral surfaces 203. In some arrangements, the circuit structure 200A is formed by disposing or forming an interconnection structure 220A over devices 210, and disposing or forming a dielectric structure 230A covering the interconnection structure 220A. The interconnection structure 220A may be or include a wafer-level interconnection structure, and the dielectric structure 230A may be or include a wafer-level dielectric structure.

In some arrangements, the devices 210 are disposed or formed on the surface 101a of the substrate 100A. In some arrangements, the devices 210 are disposed on or exposed by the surface 101a of the substrate 100A. In some arrangements, the devices 210 may be or include one or more active devices, one or more passive devices, or a combination thereof. In some arrangements, the devices 210 include one or more power devices.

In some arrangements, the interconnection structure 220A is formed by forming a plurality of conductive layers 221, 222, and 223 and forming a plurality of conductive vias 221v, 222v, and 223v electrically connecting the conductive layers 221, 222, and 223 to one another. In some arrangements, the conductive layers 221, 222, and 223 and the conductive vias 221v, 222v, and 223v are electrically connected to the devices 210. The conductive layers 221, 222, and 223 and the conductive vias 221v, 222v, and 223v may independently include a conductive material, such as a metal or metal alloy. Examples include gold (Au), silver (Ag), aluminum (Al), copper (Cu), or an alloy thereof. The number of conductive layers and the number of conductive vias of the interconnection structure 220A may vary according to actual applications.

In some arrangements, the dielectric structure 230A is formed by forming a plurality of dielectric layers 231, 232, 233, 234, 235, 236, 237, and 238 to encapsulate or cover the conductive layers 221, 222, and 223 and the conductive vias 221v, 222v, and 223v. The dielectric layers 231, 232, 233, 234, 235, 236, 237, and 238 may independently include, for example, one or more organic materials (e.g., phosphoric anhydride (PA), polyimide (PI), polybenzoxazole (PBO), epoxy, and an epoxy-based material) or one or more inorganic materials (e.g., silicon oxide, silicon nitride, glass, and ceramic). The number of dielectric layers of the dielectric structure 230A may vary according to actual applications.

In some arrangements, the metal cover 300A is disposed or formed over a top surface of the dielectric structure 230A. The metal cover 300A may have lateral surfaces 303. The metal cover 300A may be referred to as a metal coating, a protective layer, or a heat dissipation layer. The metal cover 300A is electrically insulated from the circuit structure 200A. The metal cover 300A may be referred to as a dummy metal layer. The metal cover 300A may include a metal or metal alloy. In some arrangements, the metal cover 300A and the interconnection structure 220A include different materials. The metal cover 300A may include nickel (Ni), titanium (Ti), chromium (Cr), or a combination thereof.

Referring to FIG. 1B and FIG. 1C, FIG. 1C shows a portion 1C in FIG. 1B. A laser beam L1 may be applied to the surface 101a of the structure 1000. The laser beam L1 may have a beam size L1w and at least an intensity I1 (also referred to as “a first intensity”). The term “intensity” of the laser beam used hereinafter may refer to “energy intensity” or “power” of the laser beam.

In some arrangements, the laser beam L1 includes a laser beam L1a and a laser beam L1b partially overlapped to form a central region R1 having the intensity I1 and one or more peripheral regions (e.g., regions R2 and R3) having an intensity I3 (also referred to as “a third intensity”) lower than the intensity I1. The laser beam L1 may be referred to as a dual laser beam.

In some arrangements, the laser beam L1 is applied to form at least a through trench (e.g., through trenches 200C and 300C) penetrating the metal-containing structure to expose a portion of the substrate 100A. In some arrangements, the laser beam L1 is applied to form a through trench 300C that penetrates the metal cover 300A. In some arrangements, the laser beam L1 is applied to form a through trench 200C that penetrates the interconnection structure 220A. In some arrangements, the through trenches 200C and 300C collectively form a through trench that penetrates the metal-containing structure. In some arrangements, the widths or the sizes of the through trenches 200C and 300C are determined by the beam size L1w of the laser beam L1. In some arrangements, the through trenches 200C and 300C are formed by scanning the laser beam L1 along a cutting line. In some arrangements, the circuit structure 200A is divided into circuit structures 200 by the through trench 200C, and the metal cover 300A is divided into metal covers 300 by the through trench 300C. In some arrangements, the through trench 200C is defined by lateral surfaces 204 of the circuit structures 200, and the through trench 300C is defined by lateral surfaces 304 of the metal covers 300.

According to some arrangements, the laser beam L1 has the central region R1 having a relatively high intensity to remove portions of the conductive layers 221 and 222 and the dielectric layers 231-238 that correspond to the central region R1. In addition, the laser beam L1 has the peripheral regions (e.g., the regions R2 and R3) having a relatively low intensity sufficient to remove portions of the conductive layers 221-223 and the dielectric layers 231-238 that correspond to the regions R2 and R3 so as to enlarge the sizes the through trenches 200C and 300C without generating too much heat that may damage the devices 210 and the remained portions of the conductive layers 221-223 around the through trenches 200C and 300C.

In some arrangements, the laser beam L1 is applied to further partially remove the substrate 100A to form a cavity 100C1 connected to the through trench 200C. The cavity 100C1 may be referred to as a trench. The cavity 100C1 (or the trench) may extend along the cutting line. In some arrangements, the laser beam L1 is applied to form the cavity 100C1 recessed from the surface 101a. A bottom of the cavity 100C1 may be defined by a surface 101b of the substrate 100A, and an inner sidewall of the cavity 100C1 may be defined by a lateral surface (e.g., the surface 104a) of the substrate 100A. The surfaces 101a and 101b may be referred to as portions of a surface 101 (which may be referred to as “an upper surface”) of the substrate 100A. In some arrangements, the metal-containing structure (e.g., the devices 210, the interconnection structures 220, and the metal covers 300) are disposed over the surface 101a (or the first portion of the surface 101) of the substrate 100A.

Referring to FIG. 1B and FIG. 1C, in some arrangements, the laser beam L1 is applied to further form a plurality of particles 111 dispersed in the cavity 100C1. In some arrangements, the particles 111 collectively form a microstructure layer 110 having a non-uniform thickness t1. In some arrangements, the particles 111 are formed on the surfaces 101b and 104a. In some arrangements, a portion of the substrate 100A is heated by the laser beam L1 and then transformed into the particles 111. In some arrangements, the particles 111 and the substrate 100A include the same element, e.g., silicon, carbon, or a combination thereof. In some arrangements, the substrate 100A includes SiC, and the particles 111 include a carbonized materials formed by sintering the SiC material of the substrate 100A. In some arrangements, the particles 111 have non-uniform particle sizes.

Referring to FIG. 1D and FIG. 1E, FIG. 1E shows a portion 1E in FIG. 1D. A laser beam L2 may be applied to the surface 101b of the structure 1000. The laser beam L2 may have a beam size L2w and an intensity I2 (also referred to as “a second intensity”). In some arrangements, the beam size L2w is less than the beam size L1w, and the intensity I2 is higher than the intensity I1. In some arrangements, the laser beam L1 is applied after applying the laser beam L1.

In some arrangements, the laser beam L2 is applied to further partially remove the substrate 100A. In some arrangements, the laser beam L2 is applied to form a cavity 100C2 recessed from the surface 101b (or a bottom surface of the cavity 100C1). The cavity 100C2 may be referred to as a trench. The cavity 100C2 (or the trench) may extend along the cutting line. A bottom of the cavity 100C2 may be defined by a surface 101c of the substrate 100A, and an inner sidewall of the cavity 100C2 may be defined by a lateral surface (e.g., the surface 104b) of the substrate 100A. The surface 101c may be referred to as a portion of the surface 101 (or the upper surface) of the substrate 100A. The surfaces 104a and 104b may be referred to as lateral portions of a lateral surface of the substrate 100A.

In some arrangements, a width of the cavity 100C2 is less than a width of the cavity 100C1. In some arrangements, a depth of the cavity 100C2 ranges from about 10% to about 50% of a thickness of the substrate 100A. In some arrangements, the cavity 100C1 and the cavity 100C2 taper toward the surface 102 of the substrate 100A.

According to some arrangements of the present disclosure, the cavities 100C1 and 100C2 collectively define a trench along the cutting line and configured to provide a crack that facilitates the following breaking operation to singulate the structure 1000. The depth of the cavity 100C2 is equal to or greater than about 10% of the thickness of the substrate 100A, such that the total depth of the crack (the cavities 100C1 and 100C2 combined) can be deep or long enough to facilitate the following breaking operation that separates the substrate 100A into singulated substrates 100. In addition, the depth of the cavity 100C2 is equal to or less than about 50% of the thickness of the substrate 100A, such that the total depth of the crack (the cavities 100C1 and 100C2 combined) is not too deep or long to adversely weaken the structural strength of the substrate 100A and hence cause the substrate 100A to undesirably break before the following breaking operation, which can cause the divided surfaces of the substrates 100 non-uniform with residues formed thereon. Therefore, with the design of the depth of the cavity 100C2 ranging from about 10% to about 50% of the thickness of the substrate 100A, a breaking operation for separating or dividing the substrate 100A into substrate 100 can be performed successfully, and divided surfaces of the substrates 100 formed by the breaking operation can be relatively uniform and substantially free of residues.

Referring to FIG. 1D and FIG. 1E, in some arrangements, the laser beam L2 is applied to further form a plurality of particles 121 dispersed in the cavity 100C2. In some arrangements, the particles 121 collectively form a microstructure layer 120 having a non-uniform thickness t2 and a non-uniform width w2. In some arrangements, the particles 121 are formed on the surfaces 101c and 104b. In some arrangements, a portion of the substrate 100A is heated by the laser beam L2 and then transformed into the particles 121. In some arrangements, the particles 121 and the substrate 100A include the same element, e.g., silicon, carbon, or a combination thereof. In some arrangements, the substrate 100A includes SiC, and the particles 121 include a carbonized materials formed by sintering the SiC material of the substrate 100A. In some arrangements, the particles 121 have non-uniform particle sizes.

In some arrangements, the laser beam L2 is applied to further form at least a protrusion (e.g., protrusions 110p1 and 110p2) around the cavity 100C2 and protruded beyond the bottom surface (e.g., the surface 101b) of the cavity 100C1. In some arrangements, when the laser beam L2 is applied to the surface 101b, a portion of the particles 111 may be removed by the heat from the laser beam L2, and another portion of the particles 111 may be pushed away from the cavity 100C2 to form the protrusions 110p1 and 110p2 at edges of the surface 101b.

Referring to FIG. 1F, a picture of metal covers 300 having the through trench 300C over the cavities 100C1 and 100C2 of the substrate 100A is shown. The protrusions 110p1 and 110p2 may be at edges of the cavity 100C2 and protruded beyond the surface 101b of the substrate 100A.

Referring to FIG. 1G, a breaking operation 500 may be performed to break the structure 1000 from the surface 102 of the structure 1000. In some arrangements, the substrate 100A may be broken along a cutting line 500L to form a crack that extends along the cutting line 500L from the surface 102 to the surface 101c.

Referring to FIG. 1H, the substrate 100A may be divided into substrates 100 each connected to the corresponding circuit structure 200 and the corresponding metal cover 300, so as to form singulated package structures 2A and 2A′ from the structure 1000. In some arrangements, surfaces 104c are formed after the substrates 100A is divided into the substrate 100. The surfaces 104a, 104b, and 104c may be referred to as lateral portions of the lateral surface 104 of the substrate 100. The surfaces 101a, 101b, and 101c may be referred to as portions of the surface 101 (or the upper surface) of the substrate 100.

Referring to FIG. 1I and FIG. 1J, FIG. 1I shows a picture of a cross-section of a portion of the package structure 2A without the circuit structure 200 between the metal cover 300 and the substrate 100 to represent details of the stepped structure S1, and FIG. 1J shows a picture of a side view of the surfaces 104a, 104b, and 104c.

As shown in FIG. 1H and FIG. 1J, the substrate 100 includes a stepped structure S1 defined by the surface 101 and the lateral surface 104. As shown in FIG. 1J, in some arrangements, particles (e.g., the particles 111 and 121) are formed over the surfaces 104a and 104b. As shown in FIG. 1J, in some arrangements, the surface 104c includes defects 100D extending between the surface 101 and the surface 102 and substantially free of particles.

Currently, a wafer-level structure may be divided or separated into singulated package structures by a plurality of operations. For example, a mechanical cutting operation may be used to divide the wafer-level structure. However, metal layers of the wafer-level structure may break into separated parts having non-uniform profiles or divided surface due to the mechanical cutting operation. In addition, a single laser operation may be used to divide the wafer-level structure, and the energy intensity of the single laser beam requires to be relatively high to penetrate the wafer-level structure so as to successfully divide the wafer-level structure. However, the relatively high energy intensity of the single laser beam may damage the circuit structure and/or the devices of the wafer-level structure.

According to some arrangements, the intensity I1 at the central region R1 of the laser beam L1 is lower than the intensity I2 of the laser beam L2, and the intensity I3 at the peripheral regions (e.g., the regions R2 and R3) of the laser beam L1 is even lower than the intensity I1. With the above design, the laser beam L1 is used to cut the metal-containing structure that is relatively soft compared to the substrate 100A yet having circuits and/or devices which are relatively sensitive to heat, and the laser beam L2 is used to cut the substrate 100A. Therefore, the relatively low energy intensity of the laser beam L1 is sufficient to cut or divide the metal-containing structure, and only the relatively rigid substrate 100A is cut or divided by the relatively high energy intensity of the laser beam L2, such that the devices 210 and the remained portions of the conductive layers 221-223 around the through trenches 200C and 300C of the metal-containing structure can be prevented from being damaged by too much heat generated by the laser beam L2.

In addition, according to some arrangements of the present disclosure, the cavity 100C2 formed by the laser beam L2 is relatively narrow and located close to the surface 102 on which the breaking operation is performed. Therefore, the relatively narrow cavity 100C2 can help induce the crack generated by the breaking operation to align with the cavities 100C1 and 100C2 so as to divide the structure 1000 along the cutting line successfully.

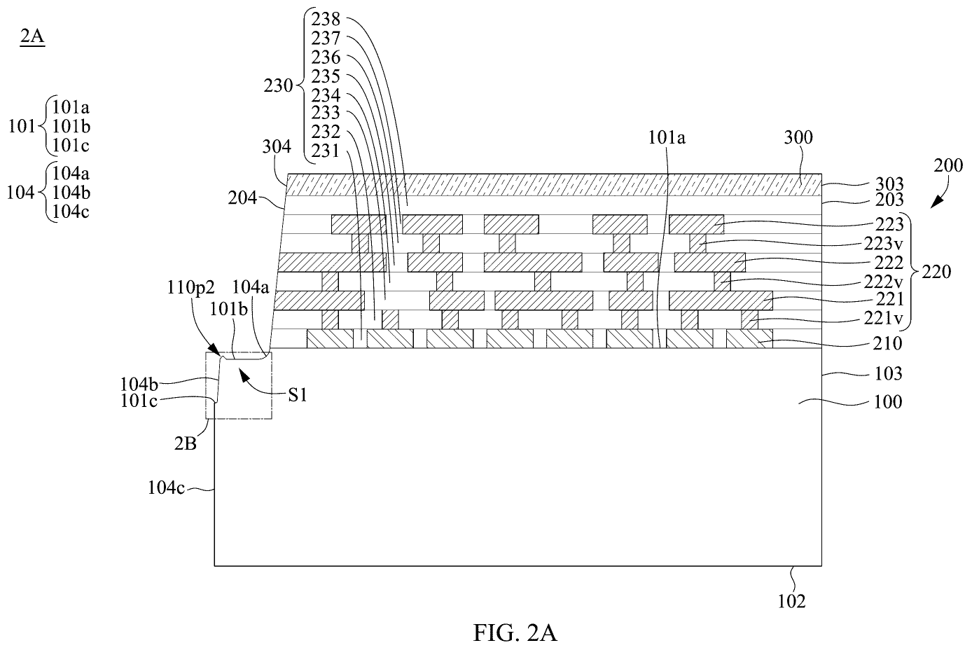

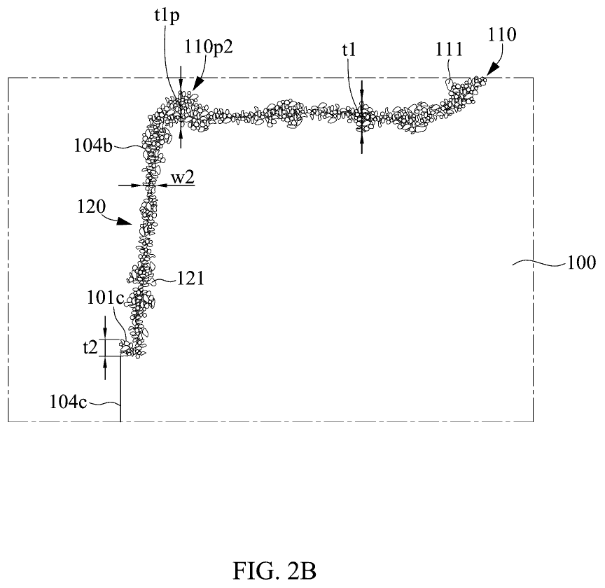

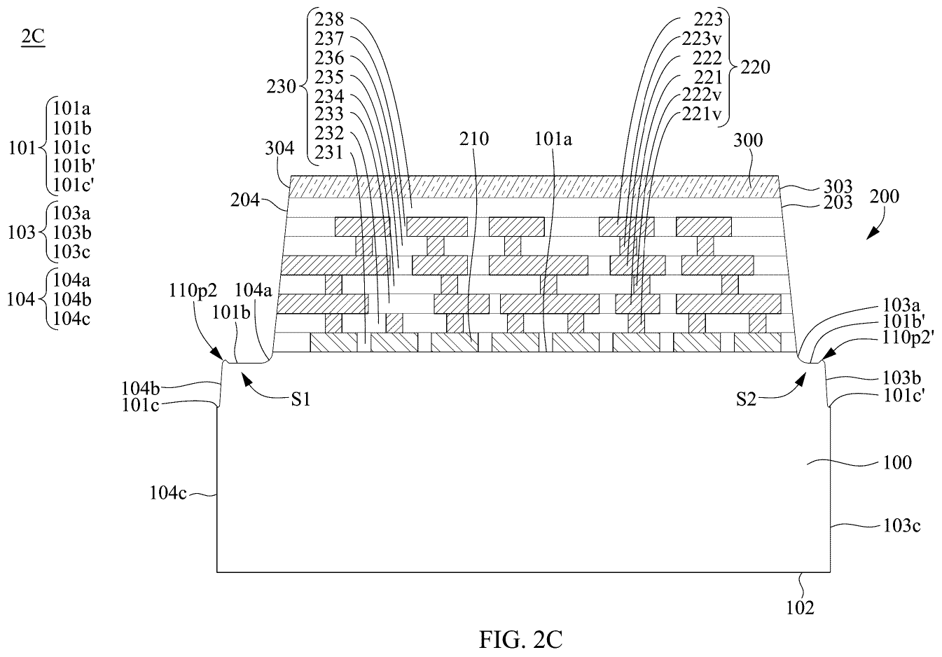

FIG. 2A is a cross-section of a package structure 2A in accordance with some arrangements of the present disclosure. FIG. 2B is a cross-section of a portion of a package structure 2A in accordance with some arrangements of the present disclosure. In some arrangements, FIG. 2B is a cross-section of a portion 2B of the package structure 2A illustrated in FIG. 2A. The package structure 2A includes a substrate 100 and a metal-containing structure over the substrate 100. In some arrangements, the metal-containing structure includes a circuit structure 200 and a metal cover 300.

The substrate 100 may have an upper surface (e.g., the surface 101), a lower surface (e.g., the surface 102), and lateral surfaces 103 and 104 extending between the surface 101 and the surface 102. In some arrangements, the substrate 100 includes a stepped structure S1 defined by the surface 101 and the lateral surface 104, and the stepped structure S1 has a non-uniform roughness. In some arrangements, the substrate 100 includes microstructure layers 110 and 120 and protrusions 110p1 and 110p2.

In some arrangements, the lateral surface 104 includes lateral portions (e.g., the surfaces 104a, 104b, and 104c) defining sidewalls of the stepped structure S1, and the lateral portions have different roughness. In some arrangements, the surface 104a is connected to the surface 101, the surface 104c is connected to the surface 102, and a roughness of the surface 104a is greater than a roughness of the surface 104c. In some arrangements, the surface 104b is between and misaligned with the surface 104a and the surface 104c, and a roughness of the surface 104b is greater than the roughness of the surface 104c.

In some arrangements, the surface 101 (or the upper surface) includes portions (e.g., the surfaces 101a, 101b, and 101c) at different elevations and defining stepped surfaces of the stepped structure S1. In some arrangements, a roughness of the surface 101b and a roughness of the surface 101c are greater than a roughness of the surface 101a.

In some arrangements, the metal-containing structure is disposed over the surface 101a and substantially free from vertically overlapping the surfaces 101b and 101c. In some arrangements, the circuit structure 200 and the metal cover 300 are disposed over the surface 101a and substantially free from vertically overlapping the surfaces 101b and 101c. In some arrangements, the lateral surface 203 is substantially perpendicular to the surface 101a, and the lateral surface 204 is non-parallel to the lateral surface 203. In some arrangements, the lateral surface 303 is substantially perpendicular to the surface 101a, and the lateral surface 304 is non-parallel to the lateral surface 303. The description of the metal-containing structure (e.g., the circuit structure 200 and the metal cover 300) is the same as or similar to those described above and is not repeated hereinafter.

Referring to FIG. 2B, in some arrangements, the microstructure layer 110 including a plurality of particles 111 is disposed or formed over the surface 101b (or a portion of the surface 101) of the substrate 100, and an elevation of the surface 101b is lower than an elevation of the surface 101a with respect to the surface 102.

Referring to FIG. 2B, in some arrangements, the microstructure layer 120 including a plurality of particles 121 is disposed or formed over the surface 104a (or a lateral portion of the lateral surface 104) of the substrate 100 and free from covering the surface 104c (or a lateral portion of the lateral surface 104). In some arrangements, the microstructure layer 120 extends over the surface 101c (or a portion of the surface 101) that is at an elevation lower than the elevation of the surface 101b with respect to the surface 102. In some arrangements, the particles 111, the particles 121, and the substrate 100 include the same element, e.g., silicon, carbon, or a combination thereof.

Referring to FIG. 2B, in some arrangements, each of the protrusions 110p1 and 110p2 includes a plurality of the particles 111 and 121 and between the microstructure layer 110 and the microstructure layer 120.

Referring to FIG. 2A and FIG. 1J, in some arrangements, the surface 104c of the substrate 100 of the package structure 2A includes defects 100D extending between the surface 101 and the surface 102 and substantially free of particles 111 and 121.

FIG. 2C is a cross-section of a package structure 2C in accordance with some arrangements of the present disclosure. The package structure 2C is similar to the package structure 2A shown in FIG. 2A, and the differences therebetween are described as follows.

In some arrangements, the substrate 100 further has surfaces 101a, 101b′, and 101c′ at different elevations. The surfaces 101a, 101b, 101c, 101b′, and 101c′ may be referred to as portions of the surface 101 (or the upper surface) of the substrate 100. In some arrangements, the substrate 100 has surfaces 103a, 103b, and 103c. The surfaces 103a, 103b, and 103c may be referred to as lateral portions of the lateral surface 103 of the substrate 100. In some arrangements, the substrate 100 further includes microstructure layers (which are similar to the microstructure layers 110 and 120) including particles (which are similar to the particles 111 and 121) over the surfaces 103a, 101b′, 103b, and 101c′.

In some arrangements, the substrate 100 further includes a stepped structure S2 defined by the surface 101 and the lateral surface 103 opposite to the lateral surface 104, and the stepped structure S2 has a non-uniform roughness. In some arrangements, the substrate 100 further includes a protrusion 110p2′ between the surface 101b′ and the surface 103b. The stepped structure S2 is similar to the stepped structure S1, and the description thereof is omitted hereinafter.

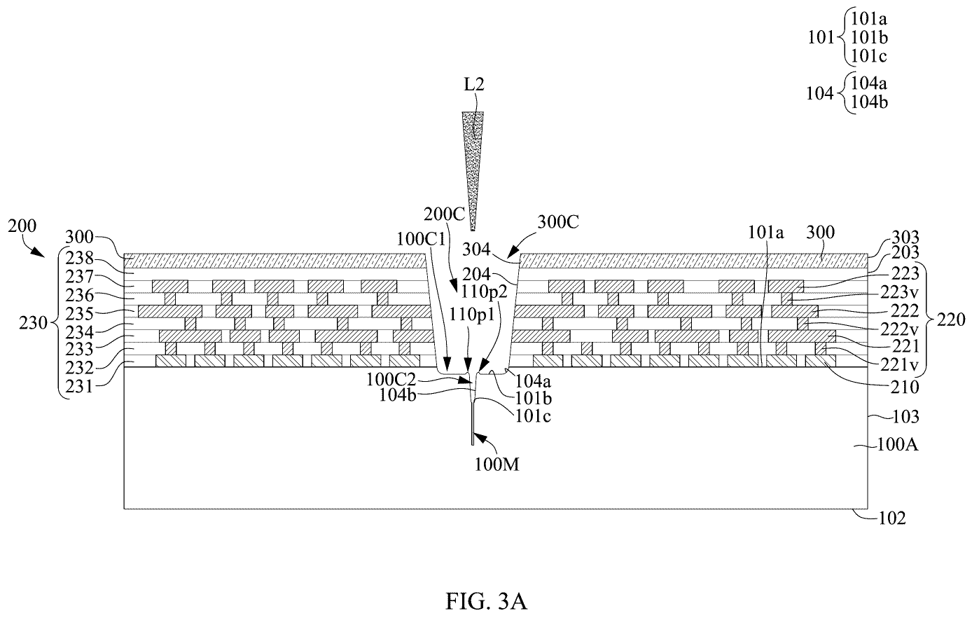

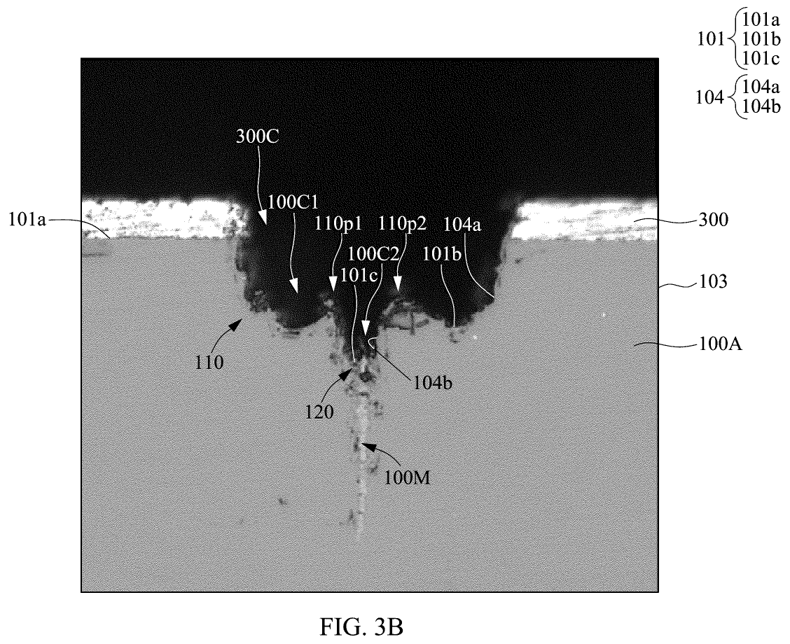

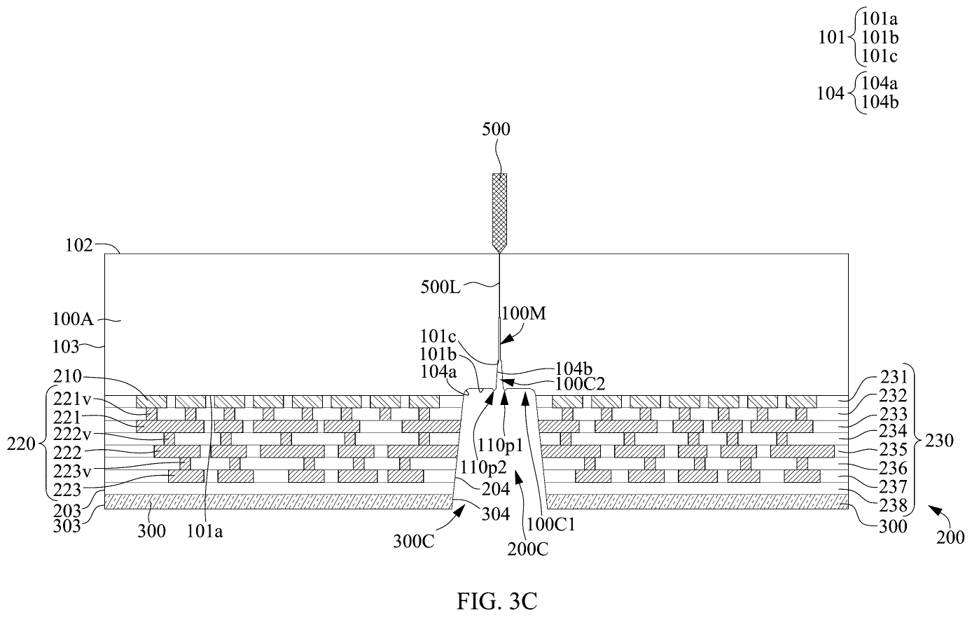

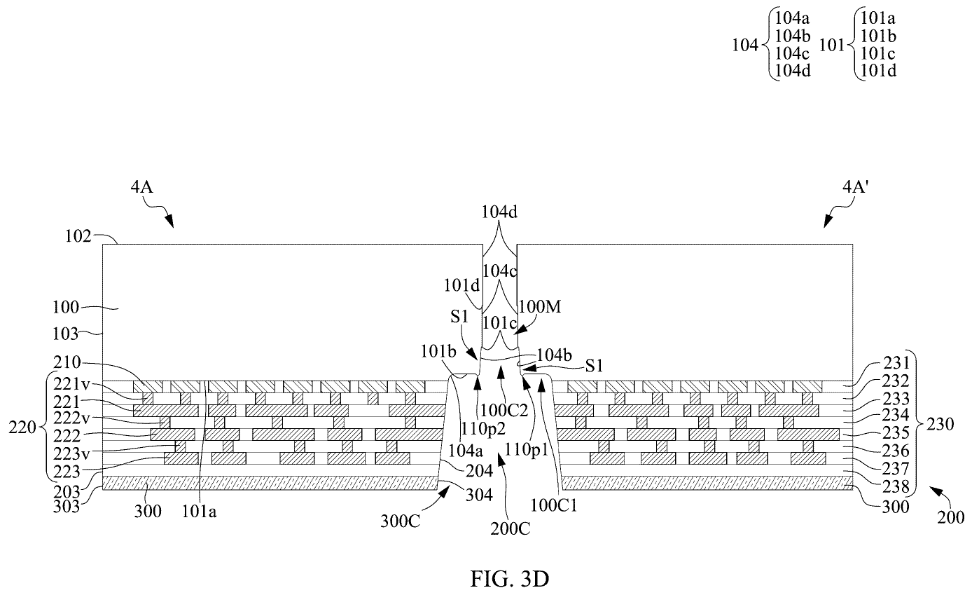

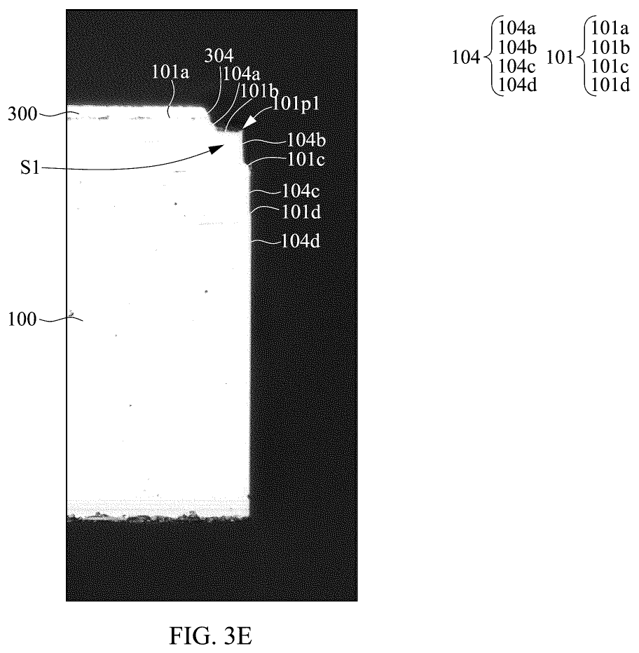

FIG. 3A, FIG. 3B, FIG. 3C, FIG. 3D, and FIG. 3E illustrate various stages of an example of a method of manufacturing a package structure in accordance with some arrangements of the present disclosure.

Referring to FIG. 3A and FIG. 3B, a picture of metal covers 300 having the through trench 300C over the cavities 100C1 and 100C2 of the substrate 100A is shown in FIG. 3B. operations similar to those illustrated in FIGS. 1A-1C may be performed to apply a laser beam L1 to form through trenches 200C and 300C and a cavity 100C1, and operations similar to those illustrated in FIGS. 1D-1E may be performed to apply a laser beam L2 to form a cavity 100C2 and a crack region 100M extending from a bottom surface (e.g., the surface 101c) of the cavity 100C2 in a direction away from the surface 101a of the substrate 100A. In some arrangements, a width of the crack region 100M is less than a width of the cavity 100C2. The crack region 100M may be formed by the heat impact or the thermal impact from the laser beam L2. In some arrangements, the crack region 100M includes a cavity connected to the cavity 100C2, a modification layer formed of a portion of the substrate 100A, or a combination thereof.

According to some arrangements of the present disclosure, by varying the parameters of the laser beam L2 applied to the substrate 100A, the crack region 100M may be formed as a modification layer or a cavity that extends along the cutting line. Therefore, the modification layer can serve as a weak point that extends along the cutting line to facilitate the following breaking operation.

Referring to FIG. 3C, a breaking operation 500 may be performed to break the structure 1000 from the surface 102 of the structure 1000. In some arrangements, the substrate 100A may be broken along a cutting line 500L and the crack region 100M that extends along the cutting line 500L from the surface 102 to the surface 101c.

Referring to FIG. 3D and FIG. 3E, a picture of a cross-section of a portion of the package structure 4A without the circuit structure 200 between the metal cover 300 and the substrate 100 is shown in FIG. 3E to represent details of the stepped structure S1. As shown in FIG. 3D, the substrate 100A may be divided into substrates 100 each connected to the corresponding circuit structure 200 and the corresponding metal cover 300, so as to form singulated package structures 4A and 4A′ from the structure 1000. In some arrangements, surfaces 101d and 104d are formed after the substrates 100A is divided into the substrate 100. The surfaces 104a, 104b, 104c, and 104d may be referred to as lateral portions of the lateral surface 104 of the substrate 100. The surfaces 101a, 101b, 101c, and 101d may be referred to as portions of the surface 101 (or the upper surface) of the substrate 100.

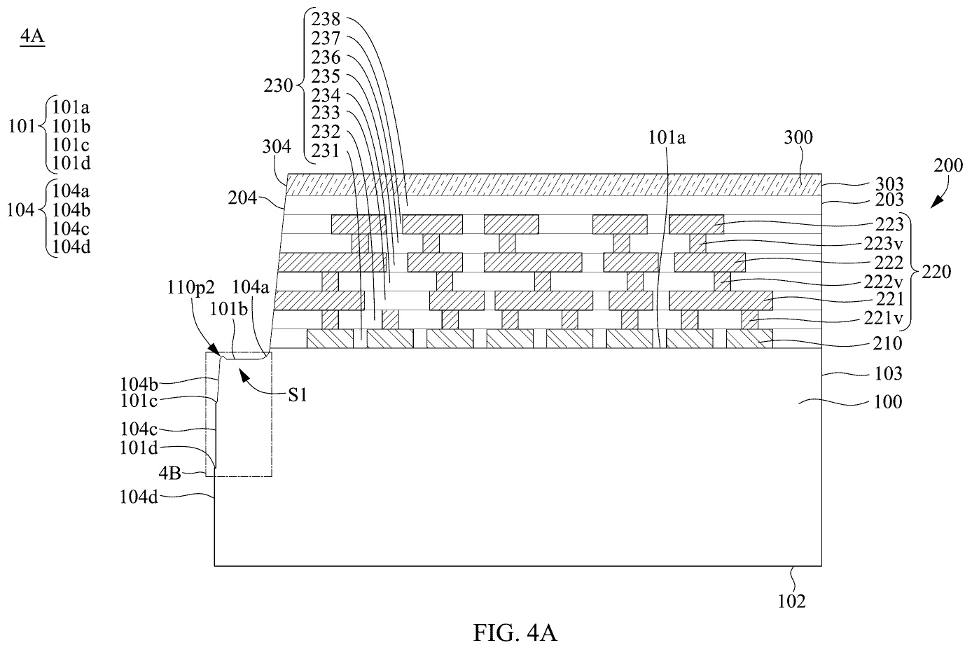

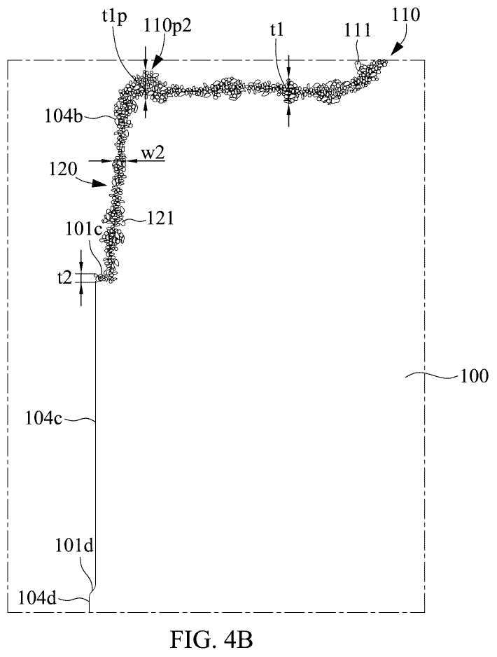

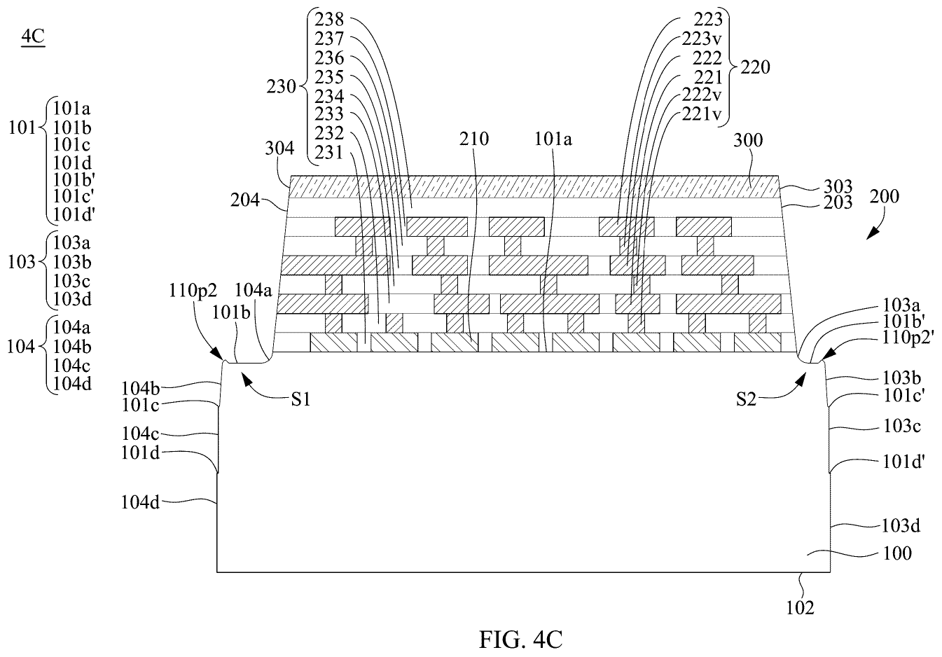

FIG. 4A is a cross-section of a package structure 4A in accordance with some arrangements of the present disclosure. FIG. 4B is a cross-section of a portion of a package structure 4A in accordance with some arrangements of the present disclosure. In some arrangements, FIG. 4B is a cross-section of a portion 4B of the package structure 4A illustrated in FIG. 4A. The package structure 4A includes a substrate 100 and a metal-containing structure over the substrate 100. In some arrangements, the metal-containing structure includes a circuit structure 200 and a metal cover 300. The package structure 4A is similar to the package structure 2A shown in FIG. 2A, and the differences therebetween are described as follows.

In some arrangements, the stepped structure S1 is defined by the surfaces 101a, 101b, 101c, 101d, 104a, 104b, 104c, and 104d. In some arrangements, the stepped structure S2 includes stepped surfaces (e.g., the surfaces 101a, 101b, 101c, and 101d) at different elevations. In some arrangements, referring to FIG. 4B, the surfaces 101d, 104c, and 104d are substantially free of particles 111 and 121.

FIG. 4C is a cross-section of a package structure 4C in accordance with some arrangements of the present disclosure. The package structure 4C is similar to the package structure 4A shown in FIG. 4A, and the differences therebetween are described as follows.

In some arrangements, the substrate 100 further has surfaces 101a, 101b′, 101c′, and 101d′ at different elevations. The surfaces 101a, 101b, 101c, 101d, 101b′, 101c′, and 101d′ may be referred to as portions of the surface 101 (or the upper surface) of the substrate 100. In some arrangements, the substrate 100 has surfaces 103a, 103b, 103c, and 103d. The surfaces 103a, 103b, 103c, and 103d may be referred to as lateral portions of the lateral surface 103 of the substrate 100. In some arrangements, the substrate 100 further includes microstructure layers (which are similar to the microstructure layers 110 and 120) including particles (which are similar to the particles 111 and 121) over the surfaces 103a, 101b′, 103b, and 101c′.

In some arrangements, the substrate 100 further includes a stepped structure S2 defined by the surface 101 and the lateral surface 103 opposite to the lateral surface 104, and the stepped structure S2 has a non-uniform roughness. In some arrangements, the substrate 100 further includes a protrusion 110p2′ between the surface 101b′ and the surface 103b. The stepped structure S2 is similar to the stepped structure S1, and the description thereof is omitted hereinafter.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of manufacturing a package structure, comprising:
providing a structure comprising a substrate and a metal-containing structure over the substrate;
applying a first laser beam to a first surface of the structure, the first laser beam having a first beam size and at least a first intensity;
applying a second laser beam to the first surface of the structure, wherein the second laser beam has a second beam size less than the first beam size and a second intensity higher than the first intensity; and
breaking the structure from a second surface opposite to the first surface of the structure.

2. The method as claimed in claim 1, wherein applying the first laser beam forms a through trench penetrating the metal-containing structure and partially removes a portion of the substrate to form a cavity connected to the through trench.

3. The method as claimed in claim 2, wherein applying the first laser beam further forms a plurality of particles dispersed in the cavity.

4. The method as claimed in claim 1, wherein applying the first laser beam forms a first cavity recessed from a first portion of the first surface of the substrate, and the metal-containing structure is disposed over the first portion of the first surface of the substrate.

5. The method as claimed in claim 4, wherein applying the second laser beam forms a second cavity recessed from a bottom surface of the first cavity, wherein a width of the second cavity is less than a width of the first cavity.

6. The method as claimed in claim 5, wherein a depth of the second cavity ranges from about 10% to about 50% of a thickness of the substrate.

7. The method as claimed in claim 5, wherein applying the second laser beam further forms at least a protrusion around the second cavity and protruded beyond the bottom surface of the first cavity.

8. The method as claimed in claim 5, wherein applying the first laser beam further forms a plurality of first particles dispersed in the first cavity, and applying the second laser beam forms a plurality of second particles dispersed in the second cavity.

9. The method as claimed in claim 5, wherein applying the second laser beam further forms a crack region extending from a bottom surface of the second cavity in a direction away from the first surface of the substrate.

10. A package structure, comprising:
a substrate having an upper surface, a lower surface, and a first lateral surface extending between the upper surface and the lower surface, wherein the substrate comprises a first stepped structure defined by the upper surface and the first lateral surface and having a non-uniform roughness; and
a metal-containing structure over the upper surface.

11. The package structure as claimed in claim 10, wherein the first lateral surface comprises a first lateral portion and a second lateral portion defining sidewalls of the first stepped structure and having different roughness.

12. The package structure as claimed in claim 11, wherein the first lateral portion is connected to the upper surface, the second lateral portion is connected to the lower surface, and a roughness of the first lateral portion is greater than a roughness of the second lateral portion.

13. The package structure as claimed in claim 11, wherein the first lateral surface further comprises a third lateral portion defining an additional sidewall of the first stepped structure and having a roughness different from that of the first lateral portion and the second lateral portion.

14. The package structure as claimed in claim 13, wherein the third lateral portion is between and misaligned with the first lateral portion and the second lateral portion, the second lateral portion is connected to the lower surface, and a roughness of the third lateral portion is greater than a roughness of the second lateral portion.

15. The package structure as claimed in claim 14, wherein the roughness of the third lateral portion is different from a roughness of the first lateral portion.

16. A package structure, comprising:
a substrate having an upper surface, a lower surface, and a first lateral surface extending between the upper surface and the lower surface;
a circuit structure over a first portion of the upper surface; and
a first microstructure layer comprising a plurality of first particles over a first portion of the first lateral surface and free from covering a second portion of the first lateral surface.

17. The package structure as claimed in claim 16, further comprising a second microstructure layer comprising a plurality of second particles over a second portion of the upper surface, wherein an elevation of the second portion is lower than an elevation of the first portion with respect to the lower surface.

18. The package structure as claimed in claim 17, further comprising a protrusion comprising a plurality of particles between the first microstructure layer and the second microstructure layer.

19. The package structure as claimed in claim 17, wherein the first microstructure layer extends over a third portion of the upper surface at an elevation lower than the elevation of the second portion with respect to the lower surface.

20. The package structure as claimed in claim 16, wherein the second portion of the first lateral surface (comprises defects extending between the upper surface and the lower surface.
